(19) United States
(12) Patent Application Publication
(10) Pub. No.: US 2026/0128666 A1
(43) Pub. Date: May 7, 2026

(54) POWER CONVERSION SYSTEM AND FAULTY UNIT SEPARATION METHOD FOR POWER CONVERSION SYSTEM

(71) Applicant: MEIDENSHA CORPORATION, Shinagawa-ku, Tokyo (JP)

(72) Inventor: Hayato HIGA, Mishima-shi, Shizuoka (JP)

(73) Assignee: MEIDENSHA CORPORATION, Shinagawa-ku, Tokyo (JP)

(21) Appl. No.: 19/485,219

(22) PCT Filed: Mar. 8, 2024
(86) PCT No.: PCT/JP2024/009059

§ 371 Date: Nov. 17, 2025

(30) Foreign Application Priority Data
May 18, 2023 (JP) 2023-081958

(51) Int. Cl. H02M 1/32; G01R 31/42; G01R 31/52; H02M 1/00; H02M 1/088; H02M 3/335; H02M 7/797

(52) U.S. Cl. CPC H02M 1/32; G01R 31/42; G01R 31/52; H02M 1/007; H02M 1/088; H02M 3/33573; H02M 3/33584; H02M 3/33592; H02M 7/797

(57) ABSTRACT

An object of the present invention is to separate a failure-detected cell from an SST type power conversion system while suppressing overvoltage and overcurrent. In the system in which a plurality of power converter units (cells) each having an AC/DC converter, an isolated DC/DC primary converter, and an isolated DC/DC secondary converter, are provided, and AC-side terminals of the units (cells) are connected in series, and DC-side terminals of the units (cells) are connected in parallel, a switch SWin to short-circuit the AC-side terminals and a switch SWout to disconnect parallel connection of the DC-side terminals are provided. A short-circuit detected location in each converter in each cell is determined (step S11). After a gate of a short-circuit detected converter is blocked (S12a, S12b), a gate of a short-circuit undetected converter is blocked (S13a, S13b). AC-side switch SWin is turned on (S14), and DC-side switch SWout is turned off (S15).

### TECHNICAL FIELD

The present invention relates to a method of safely disconnecting a cell that has been failed and detected from an SST (Solid State Transformer) type power conversion system configured by a plurality of power converter units (cells) connected in series or in parallel.

### BACKGROUND ART

An example of a circuit configuration of the SST type power conversion system is shown in FIG. 1. In FIG. 1, a reference numeral 11 denotes an AC/DC converter that converts AC power into DC power. An AC side of the AC/DC converter 11 is connected to AC-side terminals 10a and 10b.

An AC-side switch Swin (an input-side system separation switch) to short-circuit the AC-side terminals 10a and 10b is connected between the AC-side terminals 10a and 10b.

A reference numeral 12 denotes an isolated DC/DC converter. The isolated DC/DC converter 12 includes, as will be described later, a primary single-phase power converter whose DC side is connected to a DC side of the AC/DC converter 11, an isolated transformer whose primary winding is connected to an AC side of the primary single-phase power converter, and a secondary single-phase power converter whose AC side is connected to a secondary winding of the isolated transformer.

Positive and negative terminals of a DC output-side (the secondary single-phase power converter) of the isolated DC/DC converter 12 are connected to DC-side terminals 10c and 10d via a DC-side switch SWout (an Output-side system separation switch).

The AC-side switch SWin, the AC/DC converter 11, the isolated DC/DC converter 12, and the DC-side switch SWout constitute one power converter unit (hereinafter, also referred to as a cell) 10.

Here, an AC-side capacitor (a primary capacitor) C1, which is omitted in FIG. 1 though, is connected between DC-side positive and negative lines connecting the AC/DC converter 11 and the isolated DC/DC converter 12. Also, a DC-side capacitor (a secondary capacitor) C2, which is omitted in FIG. 1 though, is connected between DC output-side positive and negative terminals of the isolated DC/DC converter 12.

A plurality of power converter units 10 (cell No. 1 to cell No. n) are provided. The AC-side terminals 10a and 10b of one power converter unit 10 are connected to the AC-side terminals 10a and 10b of next power converter unit 10 in series (so that the AC-side terminal 10b of the cell No. 1 is connected to the AC-side terminal 10a of the cell No. 2).

The DC-side terminals 10c and 10d of one power converter unit 10 are connected to the DC-side terminals 10c and 10d of the other power converter units 10 in parallel (so that the DC-side terminals 10c of the cell No. 1 to the cell No. n are connected in common, and the DC-side terminals 10d of the cell No. 1 to the cell No. n are connected in common).

It is noted that, in a case where each power converter unit 10 is not disconnected (separated), the AC-side switch SWin is turned off (is in an open circuit state), and the DC-side switch SWout is turned on (is in a closed circuit state).

Next, examples of a circuit configuration of the power converter unit (the cell) 10 will be described with reference to FIGS. 2A to 2C. In FIGS. 2A to 2C, the same element or component as that in FIG. 1 is denoted by the same reference symbol. FIG. 2A illustrates a circuit configuration of the power converter unit of a unidirectional power supply type using an LLC resonant converter.

A reference numeral 11 denotes an AC/DC converter configured by bridge-connected semiconductor switches SW1 to SW4. An AC-side capacitor (a primary capacitor) C1 is connected between DC-side positive and negative terminals of the AC/DC converter 11.

A reference numeral 121 denotes an isolated DC/DC primary converter (a primary single-phase power converter) configured by bridge-connected semiconductor switches SW5 to SW8. A DC side of the isolated DC/DC primary converter 121 is connected to a DC side of the AC/DC converter 11.

An AC side of the isolated DC/DC primary converter 121 is connected to a primary winding of a current resonance transformer Tr via reactors L1 and L2 and current resonance capacitors C3 and C4. The reactors L1 and L2 may be omitted.

The primary and secondary windings of the current resonance transformer Tr have a winding ratio of 1:N. The secondary winding is connected to an AC side of an isolated DC/DC secondary converter (a secondary single-phase power converter) 122a configured by bridge-connected diodes D1 to D4.

A DC-side capacitor (a secondary capacitor) C2 is connected between DC-side positive and negative terminals of the isolated DC/DC secondary converter 122a.

FIG. 2B illustrates a power converter of a bidirectional power supply type using a DAB (Dual Active Bridge) converter. An AC/DC converter 11, an AC-side capacitor C1, and an isolated DC/DC primary converter 121 are configured in the same manner as in FIG. 2A.

An AC side of the isolated DC/DC primary converter 121 is connected to a primary winding of a transformer T via reactors L1 and L2. The primary and secondary windings of the transformer T have a winding ratio of 1:N. The secondary winding is connected to an AC side of an isolated DC/DC secondary converter 122b configured by bridge-connected semiconductor switches SW9 to SW12. A DC-side capacitor (a secondary capacitor) C2 is connected between DC-side positive and negative terminals of the isolated DC/DC secondary converter 122b.

FIG. 2C illustrates a power converter of a bidirectional power supply type using an LLC resonant converter. An AC/DC converter 11, an AC-side capacitor C1, an isolated DC/DC primary converter 121, a current resonance transformer Tr, current resonance capacitors C3 and C4, and reactors L1 and L2 are configured in the same manner as in FIG. 2A.

The secondary winding of the current resonance transformer Tr is connected to an AC side of the isolated DC/DC secondary converter 122b configured by bridge-connected semiconductor switches SW9 to SW12. A DC-side capacitor (a secondary capacitor) C2 is connected between DC-side positive and negative terminals of the isolated DC/DC secondary converter 122b.

The semiconductor switches SW1 to SW12 are configured by separately excited semiconductor switches such as MOSFETs or IGBTs.

As described above, the SST type power conversion system of FIG. 1 is capable of not only unidirectional power interchange using the circuit system shown in FIG. 2A, but also bidirectional power interchange shown in FIGS. 2B and 2C.

As a technique for disconnecting (separating) a failed cell from the power conversion system having the plurality of power converter units (cells), it has been proposed in, for instance, Patent Documents 1 and 2.

### CITATION LIST

### Patent Document

Patent Document 1: Japanese Unexamined Patent Application Publication No. 2021-141738
Patent Document 2: Japanese Unexamined Patent Application Publication No. 2022-066063

### SUMMARY OF THE INVENTION

### Technical Problem

Patent Document 1 proposes a main circuit configuration in which a bypass switch and an overvoltage suppressing element are connected in parallel to input and output of cells connected in series. With this configuration, in the event of a cell failure, only the failed cell is safely disconnected (separated) from the system while suppressing an overcurrent and an overvoltage.

Patent Document 2 can reduce surge current withstand amount of a bypass switch, thereby achieving cost reduction. Neither Patent Document 1 nor Patent Document 2 mentions how to deal with a failure when cells are connected in parallel. In addition, in order to deal with also a failure when cells are connected in parallel as in the configuration example in FIG. 1, a configuration in which a switch(es) is added is conceivable. However, an overvoltage may occur depending on the timing of cut-off (turn-off) of the additional switch(es), and normal semiconductor switches in the cells may also fail.

The present invention was made to solve the above problem. An object of the present invention is to provide a power conversion system and a failed-unit separation method which are capable of separating (disconnecting) a failure-detected cell in an SST type power conversion system from the system while suppressing an overvoltage and an overcurrent.

### Solution to Problem

To solve the above problem, a power conversion system of an SST (Solid State Transformer) type, as recited in claim 1, the power conversion system configured by a plurality of power converter units, each power converter unit including: an AC/DC converter configured to convert AC power into DC power; a primary single-phase power converter whose DC side is connected to a DC side of the AC/DC converter and whose AC side is connected to a primary winding of an isolated transformer; a secondary single-phase power converter whose AC side is connected to a secondary winding of the isolated transformer; a primary capacitor connected between DC-side positive and negative terminals of the primary single-phase power converter; and a secondary capacitor connected between DC-side positive and negative terminals of the secondary single-phase power converter, and AC-side terminals of the plurality of power converter units being connected in series, and DC-side terminals of the plurality of power converter units being connected in parallel, the power conversion system comprises: an input-side system separation switch provided at an input side of each of the plurality of power converter units, and configured to short-circuit the AC-side terminals; an output-side system separation switch provided at an output side of each of the plurality of power converter units, and configured to disconnect parallel connection of the DC-side terminals; a short-circuit detection unit configured to detect a short-circuit failure of any of the converters provided in each power converter unit; a gate block unit configured to, when a short-circuit failure is detected by the short-circuit detection unit, after blocking a gate of a semiconductor switch of a short-circuit detected converter among the AC/DC converter, the primary single-phase power converter and the secondary single-phase power converter in a short-circuit detected power converter unit, block gates of semiconductor switches of short-circuit undetected converters, or block gates of semiconductor switches of all the converters in the short-circuit detected power converter unit simultaneously; and a switch on/off unit configured to, after performing the gate-blocking by the gate block unit, turn on the input-side system separation switch, and turn off the output-side system separation switch.

In the power conversion system as recited in claim 2, in claim 1, the power converter unit is configured by a unidirectional power supply type power converter, and the switch on/off unit is configured to, after turning on the input-side system separation switch, turn off the output-side system separation switch.

In the power conversion system as recited in claim 3, in claim 1, the power converter unit is configured by a bidirectional power supply type power converter using a DAB (Dual Active Bridge) converter, or a bidirectional power supply type power converter using an LLC resonant converter, when a short-circuit failure is detected during power conversion from AC into DC by the short-circuit detection unit, the gate block unit is configured to, when performing the blocking of the gates of the semiconductor switches of the short-circuit undetected converters, first, block a gate of a semiconductor switch of one of the short-circuit undetected converters, then, block a gate of a semiconductor switch of the other of the short-circuit undetected converters, and the switch on/off unit is configured to, after turning on the input-side system separation switch, turn off the output-side system separation switch, and when a short-circuit failure is detected during power conversion from DC into AC by the short-circuit detection unit, the gate block unit is configured to, when performing the blocking of the gates of the semiconductor switches of the short-circuit undetected converters, first, block a gate of a semiconductor switch of the other of the short-circuit undetected converters, then, block a gate of a semiconductor switch of one of the short-circuit undetected converters, and the switch on/off unit is configured to, after turning off the output-side system separation switch, turn on the input-side system separation switch.

A method of separating a failure unit of a power conversion system of an SST (Solid State Transformer) type, as recited in claim 4, the power conversion system configured by a plurality of power converter units, each power converter unit including: an AC/DC converter configured to convert AC power into DC power; a primary single-phase power converter whose DC side is connected to a DC side of the AC/DC converter and whose AC side is connected to a primary winding of an isolated transformer; a secondary single-phase power converter whose AC side is connected to a secondary winding of the isolated transformer; a primary capacitor connected between DC-side positive and negative terminals of the primary single-phase power converter; and a secondary capacitor connected between DC-side positive and negative terminals of the secondary single-phase power converter, and AC-side terminals of the plurality of power converter units being connected in series, and DC-side terminals of the plurality of power converter units being connected in parallel, the method of separating the failure unit of the power conversion system comprises: a short-circuit detection step of detecting a short-circuit failure of any of the converters provided in each power converter unit, by a short-circuit detection unit; a gate block step of, when a short-circuit failure is detected by the short-circuit detection unit, after blocking a gate of a semiconductor switch of a short-circuit detected converter among the AC/DC converter, the primary single-phase power converter and the secondary single-phase power converter in a short-circuit detected power converter unit, blocking gates of semiconductor switches of short-circuit undetected converters, or blocking gates of semiconductor switches of all the converters in the short-circuit detected power converter unit simultaneously, by a gate block unit; and a switch on/off step of, after performing the gate-blocking by the gate block unit, turning on an input-side system separation switch provided at an input side of each of the plurality of power converter units and configured to short-circuit the AC-side terminals, and turning off an output-side system separation switch provided at an output side of each of the plurality of power converter units and configured to disconnect parallel connection of the DC-side terminals, by a switch on/off unit.

### Effects of Invention

(1) According to the inventions of claims 1 to 4, when a short-circuit failure is detected, only the failure detection cell can be separated (disconnected) from the system while suppressing an overvoltage and an overcurrent. Since the primary capacitor (an AC-side capacitor) does not increase significantly when separating (disconnecting) the failure detection cell, a capacitance of the capacitor can be reduced in comparison with the related art.

In addition, since a large voltage/current stress is not applied to the input-side system separation switch (a switch to short-circuit the AC-side terminals) and the output-side system separation switch (a switch to disconnect parallel connection of the DC-side terminals), a long life can be achieved.
(2) According to the invention of claim 2, the invention can be applied to the unidirectional power supply type power converter, and can be implemented with fewer steps than the bidirectional power supply type power converter. It is therefore possible to realize high-speed cut-off (high-speed disconnection).
(3) According to the invention of claim 3, the invention can be applied to both cases where a power flow is from AC to DC and the power flow is from DC to AC in the bidirectional power supply type power converter, and can obtain the same effects as in (1) in the bidirectional power flows.

### BRIEF DESCRIPTION OF THE DRAWINGS

FIG. 1 is a circuit configuration of an SST type power conversion system.

FIGS. 2A to 2C show examples of a configuration of each cell. FIG. 2A shows a circuit diagram of a power converter of a unidirectional power supply type using an LLC resonant converter. FIG. 2B shows a circuit diagram of a power converter of a bidirectional power supply type using a DAB converter. FIG. 2C shows a circuit diagram of a power converter of a bidirectional power supply type using an LLC resonant converter.

FIG. 3 is a flow chart of a process according to a first embodiment of the present invention.

FIG. 4 is a flow chart of a process upon power conversion from AC to DC according to a second embodiment of the present invention.

FIG. 5 is a flow chart of a process upon power conversion from DC to AC according to a third embodiment of the present invention.

### EMBODIMENTS FOR CARRYING OUT THE INVENTION

Embodiments of the present invention will be described in detail below with reference to the drawings. However, the present invention is not limited to the following embodiments.

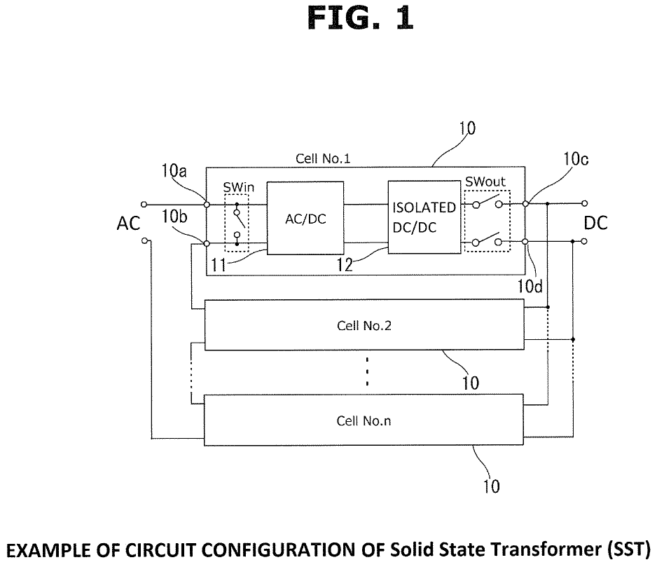

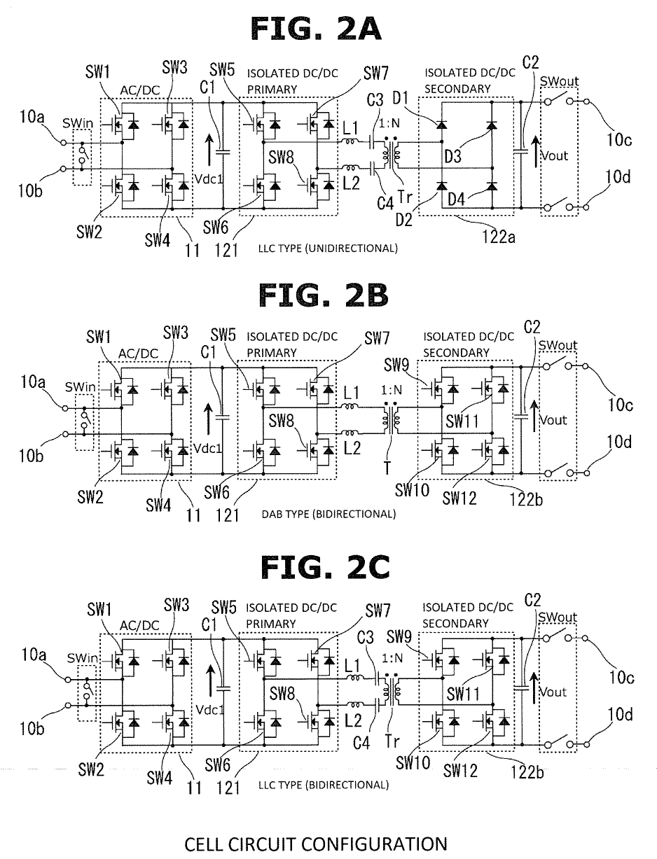

The embodiments are applied to an SST type power conversion system shown in FIGS. 1 and 2A to 2C, and include a short-circuit detection unit that detects a short-circuit failure of each converter (an AC/DC converter 11, an isolated DC/DC primary converter 121, and an isolated DC/DC secondary converter 122b) provided in each power converter unit 10, a gate block unit that blocks a gate of a semiconductor switch of each converter when the short-circuit failure is detected, and a switch on/off unit that turns on an AC-side switch SWin and turns off a DC-side switch SWout after the gate-blocking.

The short-circuit detection unit detects a short-circuit by performing a current detection method of the semiconductor switch and/or a saturation voltage measurement of the semiconductor switch.

The gate block unit performs the gate-blocking by flows shown in the following first to third embodiments, depending on a power supply type to be applied.

The switch on/off unit performs on/off by the flows shown in the following first to third embodiments, depending on the power supply type.

The AC-side switch SWin and the DC-side switch SWout may be semiconductor switches or mechanical switches such as relays.

The flows of the gate block unit and the switch on/off unit may be implemented in either hardware or software.

### First Embodiment

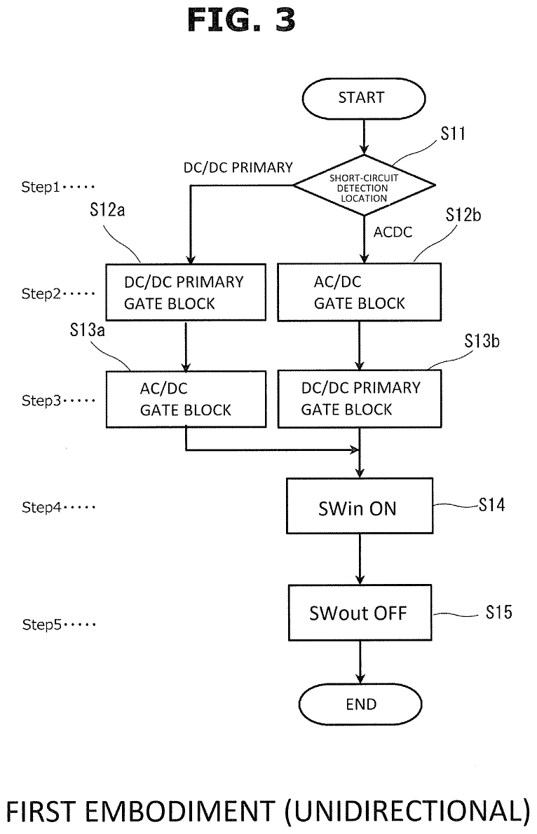

FIG. 3 illustrates a flow chart when the present invention is applied to the isolated DC/DC unidirectional type of FIG. 2A.

First, in step 1 (S11 ), a location (or portion) where a short-circuit has been detected is determined.

Next, in step 2 (S12a, S12b), by performing gate-blocking of a gate of a semiconductor switch of a power converter of the short-circuit detected location (a short-circuit detection-side power converter), a short-circuit state is opened (that is, if the short-circuit detected location is the isolated DC/DC primary converter 121, in step S12a, gate-blocking of the isolated DC/DC primary converter 121 is performed, and if the short-circuit detected location is the AC/DC converter 11, in step S12b, gate-blocking of the AC/DC converter 11 is performed).

Next, in step 3 (S13a, S13b), by performing gate-blocking of a gate of a semiconductor switch of the remaining power converter (a non-short-circuit detection-side power converter), operation of a short-circuit detection cell is stopped (that is, if the short-circuit detected location is the isolated DC/DC primary converter 121, in step S13a, gate-blocking of the AC/DC converter 11 is performed, and if the short-circuit detected location is the AC/DC converter 11, in step S13b, gate-blocking of the isolated DC/DC primary converter 121 is performed).

Next, in step 4 (S14), by turning on the AC-side switch SWin of the short-circuit failure occurrence cell, AC-side terminals 10a and 10b are bypassed (directly connected), and the short-circuit detection cell is separated (disconnected) from the AC side.

Next, in step 5 (S15), by turning off the DC-side switch SWout of the short-circuit failure occurrence cell, the short-circuit detection cell is separated (disconnected) from the DC side.

It is noted that step 2 and step 3 may be executed simultaneously. That is, the gate-blocking of the semiconductor switch of the isolated DC/DC primary converter 121 and the gate-blocking of the semiconductor switch of the AC/DC converter 11 may be performed at the same time.

As described above, according to the first embodiment, in the case of the isolated DC/DC unidirectional type power conversion system, the short-circuit detected portion can be cut off, and only the short-circuit detection cell can be separated (disconnected) from the system without an overvoltage and an overcurrent.

Furthermore, since the AC-side capacitor does not increase significantly when separating (disconnecting) the failure detection cell, a capacitance of the capacitor can be reduced in comparison with the related art.

In addition, since a large voltage/current stress is not applied to the AC-side switch SWin and the DC-side switch SWout, a long life can be achieved.

### Second Embodiment

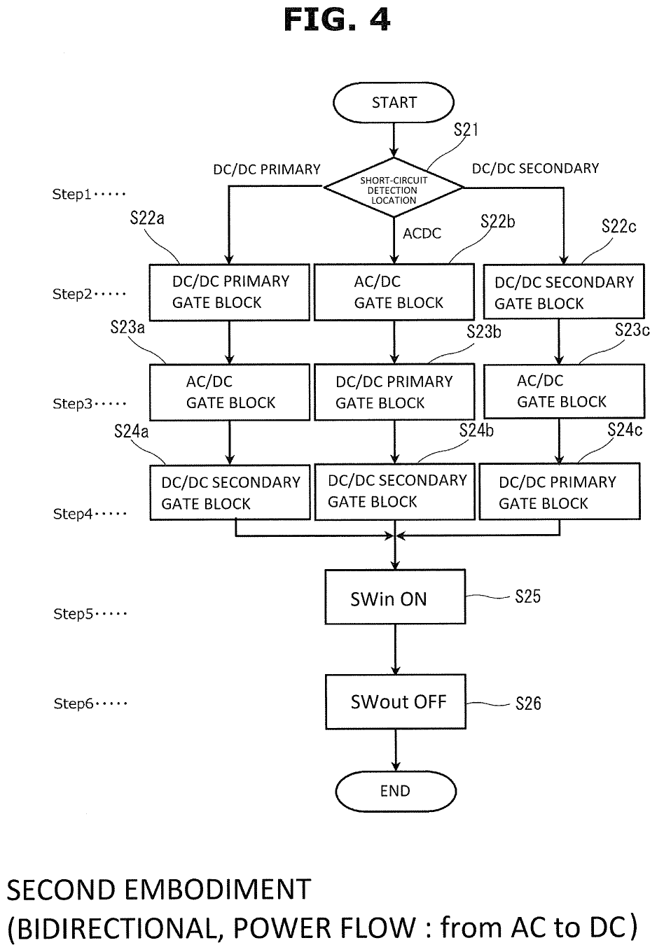

FIG. 4 illustrates a flow chart when the present invention is applied to a case where a power flow is from AC to DC in the isolated DC/DC bidirectional type of FIGS. 2B and 2C. In the bidirectional type, the semiconductor switches of the isolated DC/DC secondary converter 122b are separately excited semiconductor switches such as MOSFETs or IGBTs. Therefore, as compared with the first embodiment, the isolated DC/DC secondary converter 122b is added to the short-circuit detected location.

First, in step 1 (S21 ), a location (or portion) where a short-circuit has been detected is determined. Next, in step 2 (S22a, S22b, S22c), by performing gate-blocking of a gate of a semiconductor switch of a power converter of the short-circuit detected location (a short-circuit detection-side power converter), a short-circuit state is opened (that is, if the short-circuit detected location is the isolated DC/DC primary converter 121, in step S22a, gate-blocking of the isolated DC/DC primary converter 121 is performed, if the short-circuit detected location is the AC/DC converter 11, in step S22b, gate-blocking of the AC/DC converter 11 is performed, and if the short-circuit detected location is the isolated DC/DC secondary converter 122b, in step S22c, gate-blocking of the isolated DC/DC secondary converter 122b is performed).

Next, in step 3 (S23a, S23b, S23c), a gate of a semiconductor switch of one of the remaining power converters (one of non-short-circuit detection-side power converters) is blocked (that is, if the short-circuit detected location is the isolated DC/DC primary converter 121, in step S23a, gate-blocking of the AC/DC converter 11 is performed, if the short-circuit detected location is the AC/DC converter 11, in step S23b, gate-blocking of the isolated DC/DC primary converter 121 is performed, and if the short-circuit detected location is the isolated DC/DC secondary converter 122b, in step S23c, gate-blocking of the AC/DC converter 11 is performed).

As in steps S23a and S23c, after performing the short-circuit detection of the isolated DC/DC primary converter 121 or the isolated DC/DC secondary converter 122b and its gate-blocking, the gate-blocking of the AC/DC converter 11 is carried out. Therefore, an overvoltage of a DC voltage Vdc1 of the AC-side capacitor C1 can be prevented.

On the other hand, as in step S23b, after performing the short-circuit detection of the AC/DC converter 11 and its gate-blocking, the gate-blocking of the isolated DC/DC primary converter 121 is carried out. Therefore, the charge remaining in the AC-side capacitor C1 is not supplied to the DC side.

Next, in step 4 (S24a, S24b, S24c), by performing gate-blocking of a gate of a semiconductor switch of the other remaining power converter (the other non-short-circuit detection-side power converter), operation of a short-circuit detection cell is stopped (that is, if the short-circuit detected location is the isolated DC/DC primary converter 121, in step S24a, gate-blocking of the isolated DC/DC secondary converter 122b is performed, if the short-circuit detected location is the AC/DC converter 11, in step S24b, gate-blocking of the isolated DC/DC secondary converter 122b is performed, and if the short-circuit detected location is the isolated DC/DC secondary converter 122b, in step S24c, gate-blocking of the isolated DC/DC primary converter 121 is performed).

Next, in step 5 (S25), by turning on the AC-side switch SWin of the short-circuit failure occurrence cell, AC-side terminals 10a and 10b are bypassed (directly connected), and the short-circuit detection cell is separated (disconnected) from the AC side.

Next, in step 6 (S26 ), by turning off the DC-side switch SWout of the short-circuit failure occurrence cell, the short-circuit detection cell is separated (disconnected) from the DC side.

It is noted that at least two of steps 2 to 4 in FIG. 4 may be executed simultaneously. That is, at least two of the gate-blocking of the semiconductor switch of the AC/DC converter 11, the gate-blocking of the semiconductor switch of the isolated DC/DC primary converter 121, and the gate-blocking of the semiconductor switch of the isolated DC/DC secondary converter 122b may be performed at the same time.

As described above, according to the second embodiment, in the case of the isolated DC/DC bidirectional type power conversion system in which the power flow is from AC to DC, the short-circuit detected portion can be cut off, and only the short-circuit detection cell can be separated (disconnected) from the system without an overvoltage and an overcurrent.

### Third Embodiment

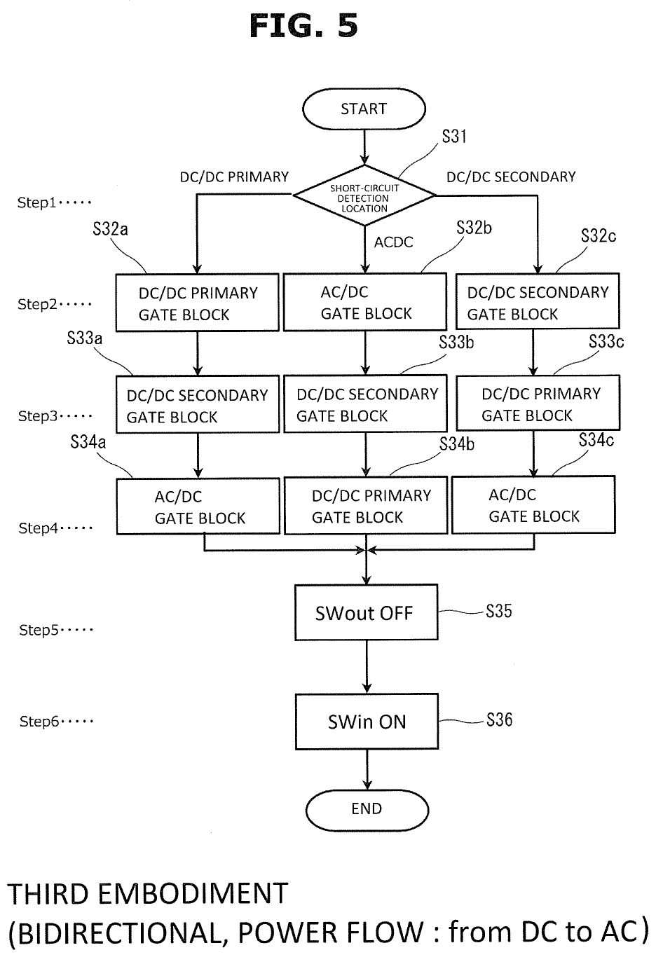

FIG. 5 illustrates a flow chart when the present invention is applied to a case where a power flow is from DC to AC in the isolated DC/DC bidirectional type of FIGS. 2B and 2C.

First, in step 1 (S31 ), a location (or portion) where a short-circuit has been detected is determined. Next, in step 2 (S32a, S32b, S32c), by performing gate-blocking of a gate of a semiconductor switch of a power converter of the short-circuit detected location (a short-circuit detection-side power converter), a short-circuit state is opened (that is, if the short-circuit detected location is the isolated DC/DC primary converter 121, in step S32a, gate-blocking of the isolated DC/DC primary converter 121 is performed, if the short-circuit detected location is the AC/DC converter 11, in step S32b, gate-blocking of the AC/DC converter 11 is performed, and if the short-circuit detected location is the isolated DC/DC secondary converter 122b, in step S32c, gate-blocking of the isolated DC/DC secondary converter 122b is performed).

Next, in step 3 (S33a, S33b, S33c), a gate of a semiconductor switch of the other of the remaining power converters (the other of non-short-circuit detection-side power converters) is blocked (that is, if the short-circuit detected location is the isolated DC/DC primary converter 121, in step S33a, gate-blocking of the isolated DC/DC secondary converter 122b is performed, if the short-circuit detected location is the AC/DC converter 11, in step S33b, gate-blocking of the isolated DC/DC secondary converter 122b is performed, and if the short-circuit detected location is the isolated DC/DC secondary converter 122b, in step S33c, gate-blocking of the isolated DC/DC primary converter 121 is performed).

As in steps S33a and S33b, after performing the gate-blocking of the isolated DC/DC primary converter 121 or the AC/DC converter 11 in step 2, the gate-blocking of the isolated DC/DC secondary converter 122b is carried out. Therefore, the power supply to the AC can be stopped.

On the other hand, as in step S33c, after performing the gate-blocking of the isolated DC/DC secondary converter 122b in step 2, the gate-blocking of the isolated DC/DC primary converter 121 is carried out. Therefore, an overvoltage of a DC voltage Vdc1 of the AC-side capacitor C1 can be prevented.

Next, in step 4 (S34a, S34b, S34c), by performing gate-blocking of a gate of a semiconductor switch of the one remaining power converter (one non-short-circuit detection-side power converter), operation of a short-circuit detection cell is stopped (that is, if the short-circuit detected location is the isolated DC/DC primary converter 121, in step S34a, gate-blocking of the AC/DC converter 11 is performed, if the short-circuit detected location is the AC/DC converter 11, in step S34b, gate-blocking of the isolated DC/DC primary converter 121 is performed, and if the short-circuit detected location is the isolated DC/DC secondary converter 122b, in step S34c, gate-blocking of the AC/DC converter 11 is performed).

Next, in step 5 (S35), by turning off the DC-side switch SWout of the short-circuit failure occurrence cell, the short-circuit detection cell is separated (disconnected) from the DC side.

Next, in step 6 (S36), by turning on the AC-side switch SWin of the short-circuit failure occurrence cell, AC-side terminals 10a and 10b are bypassed (directly connected), and the short-circuit detection cell is separated (disconnected) from the AC side.

It is noted that at least two of steps 2 to 4 in FIG. 5 may be executed simultaneously. That is, at least two of the gate-blocking of the semiconductor switch of the AC/DC converter 11, the gate-blocking of the semiconductor switch of the isolated DC/DC primary converter 121, and the gate-blocking of the semiconductor switch of the isolated DC/DC secondary converter 122b may be performed at the same time.

As described above, according to the third embodiment, in the case of the isolated DC/DC bidirectional type power conversion system in which the power flow is from DC to AC, the short-circuit detected portion can be cut off, and only the short-circuit detection cell can be separated (disconnected) from the system without an overvoltage and an overcurrent.

### DESCRIPTION OF REFERENCE SYMBOLS

10. power converter unit (cell)
10a, 10b . . . AC-side terminals
10c, 10d . . . DC-side terminals
11 . . . AC/DC converter
12 . . . isolated DC/DC converter
121 . . . isolated DC/DC primary converter
122a, 122b. . . isolated DC/DC secondary converter
C1 . . . AC-side capacitor
C2 . . . DC-side capacitor
C3, C4 . . . current resonance capacitors
D1˜D4 . . . diodes
Swin . . . AC-side switch
SWout . . . DC-side switch
SW1˜SW12 . . . semiconductor switches
T . . . transformer
Tr . . . current resonance transformer
L1, L2 . . . reactors

1. A power conversion system of an SST (Solid State Transformer) type,
the power conversion system configured by a plurality of power converter units,
each power converter unit including:
an AC/DC converter configured to convert AC power into DC power;
a primary single-phase power converter whose DC side is connected to a DC side of the AC/DC converter and whose AC side is connected to a primary winding of an isolated transformer;
a secondary single-phase power converter whose AC side is connected to a secondary winding of the isolated transformer;
a primary capacitor connected between DC-side positive and negative terminals of the primary single-phase power converter; and
a secondary capacitor connected between DC-side positive and negative terminals of the secondary single-phase power converter, and
AC-side terminals of the plurality of power converter units being connected in series, and DC-side terminals of the plurality of power converter units being connected in parallel,
the power conversion system comprising:
an input-side system separation switch provided at an input side of each of the plurality of power converter units, and configured to short-circuit the AC-side terminals;
an output-side system separation switch provided at an output side of each of the plurality of power converter units, and configured to disconnect parallel connection of the DC-side terminals;
a short-circuit detection unit configured to detect a short-circuit failure of any of the converters provided in each power converter unit;
a gate block unit configured to, when a short-circuit failure is detected by the short-circuit detection unit, after blocking a gate of a semiconductor switch of a short-circuit detected converter among the AC/DC converter, the primary single-phase power converter and the secondary single-phase power converter in a short-circuit detected power converter unit, block gates of semiconductor switches of short-circuit undetected converters, or block gates of semiconductor switches of all the converters in the short-circuit detected power converter unit simultaneously; and
a switch on/off unit configured to, after performing the gate-blocking by the gate block unit, turn on the input-side system separation switch, and turn off the output-side system separation switch.

2. The power conversion system as claimed in claim 1, wherein
the power converter unit is configured by a unidirectional power supply type power converter, and
the switch on/off unit is configured to, after turning on the input-side system separation switch, turn off the output-side system separation switch.

3. The power conversion system as claimed in claim 1, wherein
the power converter unit is configured by a bidirectional power supply type power converter using a DAB (Dual Active Bridge) converter, or a bidirectional power supply type power converter using an LLC resonant converter,
when a short-circuit failure is detected during power conversion from AC into DC by the short-circuit detection unit,
the gate block unit is configured to, when performing the blocking of the gates of the semiconductor switches of the short-circuit undetected converters, first, block a gate of a semiconductor switch of one of the short-circuit undetected converters, then, block a gate of a semiconductor switch of the other of the short-circuit undetected converters, and
the switch on/off unit is configured to, after turning on the input-side system separation switch, turn off the output-side system separation switch, and
when a short-circuit failure is detected during power conversion from DC into AC by the short-circuit detection unit, the gate block unit is configured to, when performing the blocking of the gates of
the semiconductor switches of the short-circuit undetected converters, first, block a gate of a semiconductor switch of the other of the short-circuit undetected converters, then, block a gate of a semiconductor switch of one of the short-circuit undetected converters, and
the switch on/off unit is configured to, after turning off the output-side system separation switch, turn on the input-side system separation switch.

4. A method of separating a failure unit of a power conversion system of an SST (Solid State Transformer) type,
the power conversion system configured by a plurality of power converter units,
each power converter unit including:
an AC/DC converter configured to convert AC power into DC power;
a primary single-phase power converter whose DC side is connected to a DC side of the AC/DC converter and whose AC side is connected to a primary winding of an isolated transformer;
a secondary single-phase power converter whose AC side is connected to a secondary winding of the isolated transformer;
a primary capacitor connected between DC-side positive and negative terminals of the primary single-phase power converter; and
a secondary capacitor connected between DC-side positive and negative terminals of the secondary single-phase power converter, and
AC-side terminals of the plurality of power converter units being connected in series, and DC-side terminals of the plurality of power converter units being connected in parallel,
the method of separating the failure unit of the power conversion system comprising:
a short-circuit detection step of detecting a short-circuit failure of any of the converters provided in each power converter unit;
a gate block step of, when a short-circuit failure is detected by the short-circuit detection step, after blocking a gate of a semiconductor switch of a short-circuit detected converter among the AC/DC converter, the primary single-phase power converter and the secondary single-phase power converter in a short-circuit detected power converter unit, blocking gates of semiconductor switches of short-circuit undetected converters, or blocking gates of semiconductor switches of all the converters in the short-circuit detected power converter unit simultaneously; and
a switch on/off step of, after performing the gate-blocking by the gate block step, turning on an input-side system separation switch provided at an input side of each of the plurality of power converter units and configured to short-circuit the AC-side terminals, and turning off an output-side system separation switch provided at an output side of each of the plurality of power converter units and configured to disconnect parallel connection of the DC-side terminals.
